(19) United States
(12) Patent Application Publication
(10) Pub. No.: US 2007/0216429 A1
(43) Pub. Date: Sep. 20, 2007

(54) PROBE CARD, METHOD OF DESIGNING THE PROBE CARD, AND METHOD OF TESTING SEMICONDUCTOR CHIPS USING THE PROBE CARD

(75) Inventors: Yoshinori Fukushima, Tokyo (JP); Yosuke Kawamata, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 11/685,645

(22) Filed: Mar. 13, 2007

(30) Foreign Application Priority Data
Mar. 14, 2006 (JP) 2006-069994

(51) Int. Cl. G01R 31/02

(52) U.S. Cl. 324/754

(57) ABSTRACT

A probe card has a plurality of probe needle groups arranged in a predetermined pattern. The predetermined pattern is obtained by assuming a plurality of unit regions 11-14 arranged adjacent to each other to form a chip group region. The number of unit regions is equal in number to indexes. One of the unit regions included in the chip group regions is defined as a specific unit region. A plurality of the chip group regions are arranged without space therebetween to cover a size of a wafer. The arranged chip group regions form a virtual cover pattern. The arrangement of the specific unit regions is extracted to form the predetermined pattern. Each probe needle group is arranged at the position corresponding to each specific unit region of the predetermined pattern.

### BACKGROUND OF THE INVENTION

This invention relates to a probe card, a method of designing the probe card, and a method of testing a plurality of semiconductor chips formed on a wafer by using the probe card.

In recent years, the size of a wafer is becoming large. Accordingly, the number of semiconductor chips formed on a single wafer is increasing at a large extent. In case where the number of the semiconductor chips exceeds a number of tester resources, i.e. signal line groups for use in testing the semiconductor chips, it is not possible to test all the semiconductor chips at once.

Proposals have been made for various types of probe cards for the purpose of carrying out a test in an efficient manner. Such probe cards are disclosed in, for example, JP H7-201935, JP S64-39559, and JP 2001-291750. However, the proposed probe cards are not adequate with respect to the following points.

To carry out a test in the most efficient manner, the number of indexes should be reduced. Herein, the term “index” represents a single movement of the probe card from one probing process to another probing process.

In addition, in order to reduce the cost incurred for providing probe needles on a probe card, the number of the probe needles should be as small as possible.

### SUMMARY OF THE INVENTION

It is an object of the present invention to provide a probe card capable of carrying out a test of semiconductor chips with a minimum number of indexes.

One aspect of the present invention provides a probe card for use in testing a plurality of semiconductor chips formed on a wafer. The probe card has a plurality of probe needle groups. Each of the probe needle groups has a plurality of probe needles. The probe needle groups are arranged in a predetermined pattern which has an outline of a substantial circular shape. Neighboring ones of the arranged probe needle groups are separated from each other at least in one of first and second directions by a distance corresponding to at least one of the semiconductor chips. The first and the second directions are perpendicular to each other and define a plane parallel to the principal plane of the probe card.

The predetermined pattern is obtained by: (1) assuming unit regions each comprised of at least one chip region, the chip region being substantially equal in size to one of the semiconductor chips; (2) assuming chip group regions each comprised of one or more unit regions including a specific unit region; (3) arranging the chip group regions without space therebetween to cover a size of the wafer, the arranged chip group regions forming a virtual cover pattern; and (4) extracting an arrangement of the specific unit regions from the virtual cover pattern to define the extracted arrangement as the predetermined pattern.

Another aspect of the present invention provides a method of designing a probe card for use in testing a plurality of semiconductor chips formed on a wafer, each of the semiconductor chips having a plurality of pads, the probe card having a principal plane and comprising a plurality of probe needle groups formed on the principal plane, each of the probe needle groups having a plurality of probe needles equal in number to the pads of each of the semiconductor chip. The method comprises: (1) assuming unit regions each comprised of at least one chip region, the chip region being substantially equal in size to one of the semiconductor chips; (2) assuming chip group regions each comprised of one or more unit regions including a specific unit region; (3) arranging the chip group regions without space therebetween to cover a size of the wafer, the arranged chip group regions forming a virtual cover pattern; (4) extracting an arrangement of the specific unit regions from the virtual cover pattern to define the extracted arrangement as a predetermined pattern, the predetermined pattern having an outline of a substantial circular shape; (5) arranging the probe needle groups in accordance with the predetermined pattern.

Another aspect of the present invention provides a method of testing a plurality of semiconductor chips formed on a wafer by using a probe card, neighboring ones of the semiconductor chips having a predetermined distance between their centers, each of the semiconductor chips having a plurality of pads, the probe card having a principal plane and comprising a first number of probe needle groups formed on the principal plane, each of the probe needle groups having a plurality of probe needles equal in number to the pads of each of the semiconductor chips, the probe needle groups being arranged in a predetermined pattern. The predetermined pattern is obtained by: (1) assuming unit regions each comprised of at least one chip region, the chip region being substantially equal in size to one of the semiconductor chips; (2) assuming chip group regions each comprised of a second number of unit regions including a specific unit region; (3) arranging the chip group regions without space therebetween to cover a size of the wafer, the arranged chip group regions forming a virtual cover pattern; and (4) extracting an arrangement of the specific unit regions from the virtual cover pattern to define the extracted arrangement as the predetermined pattern. The testing method comprises: (1) connecting the probe card to a tester having a third number of signal lines groups, the third number being not smaller than the first number; (2) repeatedly carrying out predetermined processes the second number of times, the predetermined processes comprising: (3) probing a fourth number of semiconductor chips once by using the probe card, the fourth number being not greater than the first number; and (4) moving the probe card in accordance with a Hamilton path by the predetermined distance once, the Hamilton path having the second number of nodes, the nodes corresponding to respective chip regions of each of the unit regions, the movement being from a current node to a next node on the Hamilton path.

An appreciation of the objectives of the present invention and a more complete understanding of its structure may be had by studying the following description of the preferred embodiment and by referring to the accompanying drawings.

### BRIEF DESCRIPTION OF THE DRAWINGS:

FIG. 1 is a schematic view showing a wafer and a plurality of semiconductor chips to be tested by a probe card according to a first embodiment of the present invention;

FIG. 2 is a schematic view showing the probe card according to the first embodiment of the present invention;

FIG. 3 shows a chip group region according to the first embodiment of the present invention;

FIG. 4 shows a process of arranging the plurality of chip group regions of FIG. 3;

FIG. 5 is a schematic view showing a virtual cover pattern formed by the plurality of chip group regions of FIG. 3;

FIG. 6 is a schematic view showing the probe card according to a second embodiment of the present invention;

FIG. 7 shows the chip group region according to the second embodiment of the present invention;

FIG. 8 is a schematic view showing the virtual cover pattern formed by the plurality of chip group regions of FIG. 7;

FIG. 9 shows another example of the chip group region;

FIG. 10 shows a process of arranging the plurality of chip group regions of FIG. 9;

FIG. 11 shows another example of the chip group region;

FIG. 12 shows a process of arranging the plurality of chip group regions of FIG. 11;

FIG. 13 shows another example of the chip group region;

FIG. 14 shows a process of arranging the plurality of chip group regions of FIG. 13;

FIG. 15 shows another example of the chip group region;

FIG. 16 shows a process of arranging the plurality of chip group regions of FIG. 15;

FIG. 17 shows another example of the chip group region;

FIG. 18 shows a process of arranging the plurality of chip group regions of FIG. 17;

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DESCRIPTION OF PREFERRED EMBODIMENTS

### First Embodiment

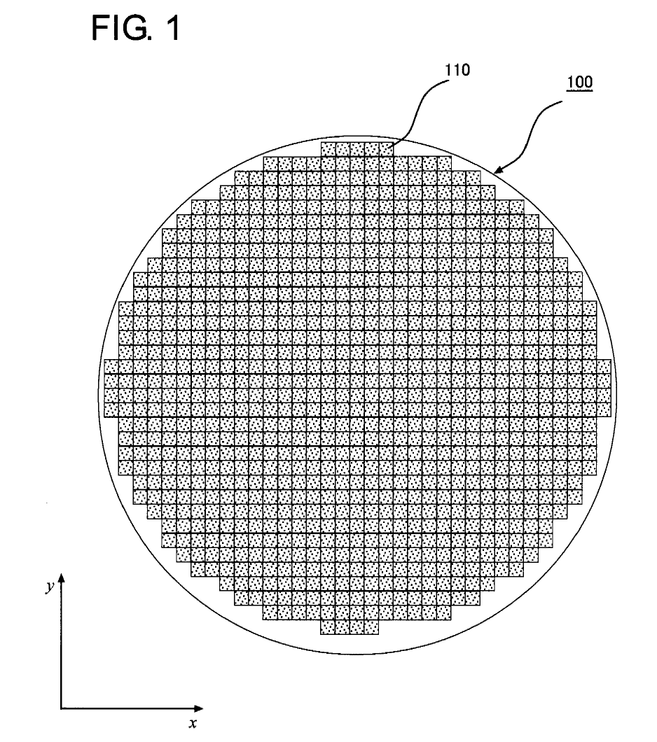

Description will be made about a probe card according to a first embodiment of the present invention with reference to FIGS. 1 to 5. FIG. 1 shows a wafer 100 and 897 pieces of semiconductor chips 110 formed on the wafer 100. All the semiconductor chips 110 have a common structure and are same as each other. Each of the semiconductor chips has a plurality of pads (not shown).

In the first embodiment, a tester (not shown) has 256 tester resources. Herein, the tester resources are a maximum number of signal line groups. The number of the tester resources indicates how many semiconductor chips can be tested at once.

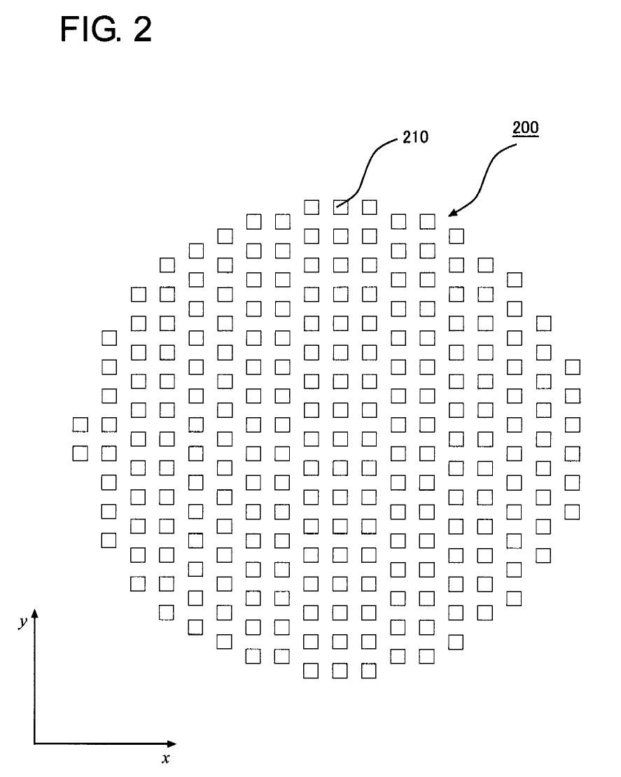

With reference to FIG. 2, a probe card 200 has 233 sets of probe needle groups 210. Each of the probe needle groups 210 has a plurality of probe needles. The probe needle groups 210 are arranged in a predetermined pattern having an outline of a substantial circular shape. In this embodiment, the neighboring ones of the arranged probe needle groups 210 are separated from each other in both x and y directions by a distance corresponding to one of the semiconductor chips.

The probe card of FIG. 2 can be obtained by the following manner.

First, the number of indexes is determined. The number of indexes can be determined on the basis of the numbers of tester resources and the number of semiconductor chips. Supposing the number of indexes is 3, the following equation gives the number of semiconductor chips which can be tested at once:

256 (number of tester resources)×3 (number of indexes)=768.

### As described above, 897 pieces of semiconductor chips 110 are formed on the wafer 100. Therefore, in order to test all the semiconductor chips on the wafer, the minimum number of indexes should be 4.

Next, the number of chip regions included in a unit region is determined. The chip region of this embodiment has a substantial square shape and a size corresponding to one of the semiconductor chips 110 In this embodiment, the unit region includes one chip region; however, the unit region may include more than two chip regions.

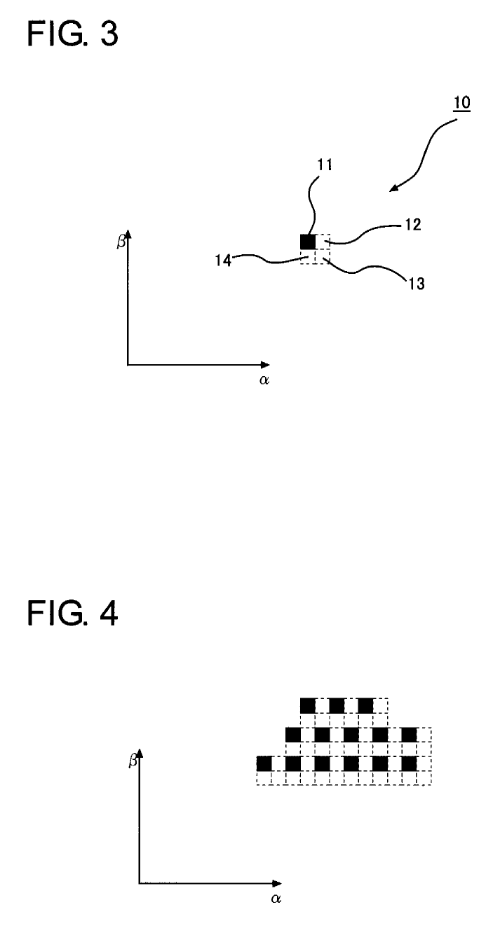

Next, with reference to FIG. 3, a chip group region 10 is formed. The chip group region 10 includes the unit regions 11-14. The number of unit regions included in the chip group region is equal in number to the indexes. In the present embodiment, four unit regions 11-14 are arranged adjacent to each other and form a substantially square shape.

One of the unit regions 11-14 included in the chip group region 10 is defined as a specific unit region. As shown in FIG. 3, one of the unit regions which is positioned at the upper left corner is defined as the specific unit region. The specific region of this embodiment is depicted by a solid square in FIG. 3.

Next, with reference to FIG. 4, a plurality of chip group regions 10 are arranged without space therebetween. Each of the chip group regions 10 has α and β axes which are perpendicular to each other. The chip group regions 10 are arranged so that the α axes of the chip group regions are directed in parallel with each other and the β axes of the chip group regions are directed in parallel with each other.

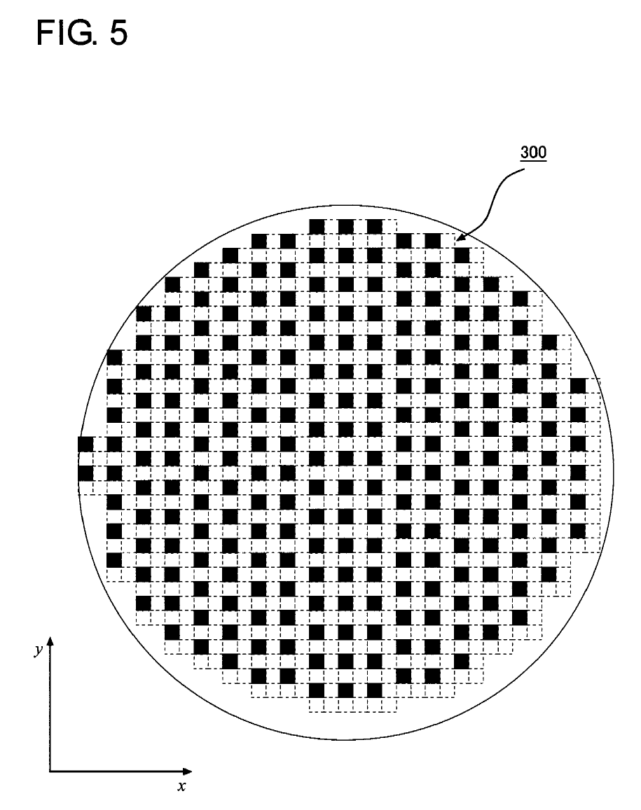

With reference to FIG. 5, a plurality of chip group regions 10 are arranged to cover a size of the wafer 100. In the present embodiment, 233 sets of chip group regions 10 are used to form a virtual cover pattern 300.

The arrangement of the specific unit regions is extracted from the virtual cover pattern 300 to define the predetermined pattern. Each of the probe needle groups 210 is arranged at the position corresponding to each of the specific unit regions. The probe needle groups 210 are equal in number to the chip group regions 10. In the present embodiment, the 233 sets of probe needle groups are used to form the probe card 200 illustrated in FIG. 2. By the use of the probe card 200, all the semiconductor chips 110 in FIG. 1 can be tested with 4 indexes.

The probe card 200 is moved along a Hamilton path. The Hamilton path has a plurality of nodes, each of the nodes corresponding to each of the unit regions 11-14. Within each chip group region 10, each of the probe needle groups 210 transfers from node to node of the Hamilton path, when the probe card 200 is moved in accordance with the Hamilton path in a clockwise direction. The probe needles of each probe needle group 210 are brought into contact with the pads of each semiconductor chip 110 at each node. Thus, all the semiconductor chips 110 can be tested with four indexes.

### Second Embodiment

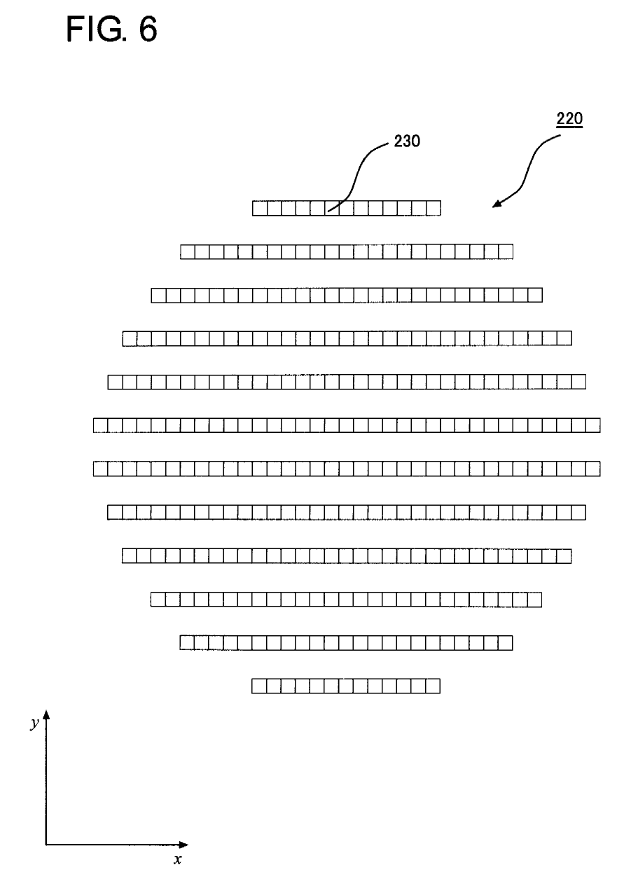

The probe card 220 according to a second embodiment has a plurality of probe needle groups 230 arranged in a predetermined pattern as shown in FIG. 6. The predetermined pattern has a plurality of bars which are arranged perpendicular to a y direction. The bars are spaced at regular intervals and are arranged parallel to each other in the y direction. Each of the bars has a different length in an x direction. As shown in FIG. 6, the predetermined pattern has an outline of a substantial circular shape.

In the second embodiment, the structure and the arrangement of the semiconductor chips 110 are same as those described in the first embodiment. The tester has 384 units of tester resources. Accordingly, the number of indexes is determined as 3. In this embodiment, the unit region includes one chip region.

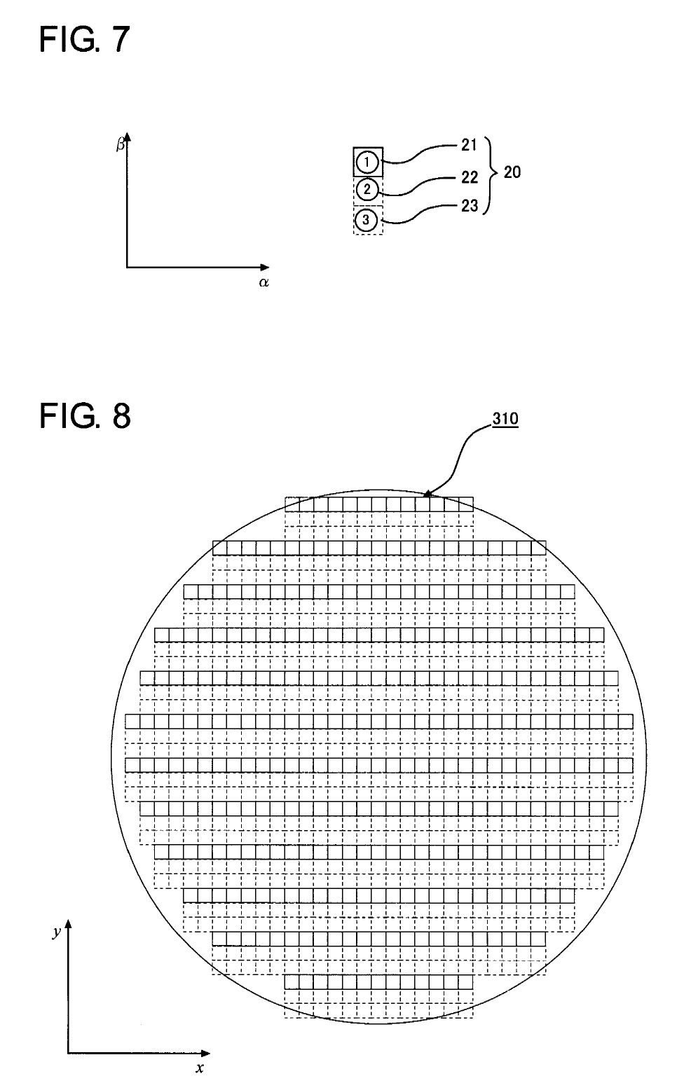

With reference to FIG. 7, a plurality of unit regions equal in number to the indexes form a chip group region. In this case, one chip group region 20 is formed of three unit regions 21-23. The unit regions 21-23 are aligned perpendicular to a direction and that the chip group region has an I-shape.

One of the unit regions 21-23 included in the chip group region 20 is defined as a specific unit region. As shown in FIG. 7, one of the unit regions which is positioned at the top is defined as the specific unit region and is depicted by solid lines in FIG. 7. The remaining unit regions 22 and 23 are depicted by broken lines.

Next with reference to FIG. 8, a plurality of chip group regions 20 are arranged without space therebetween. Each of the chip group regions 20 has x and y axes which are perpendicular to each other. The chip group regions 20 are arranged so that the x axes of the chip group regions are directed in parallel with each other and the y axes of the chip group regions are directed in parallel with each other.

The plurality of chip group regions 20 are arranged to cover a size of the wafer 100. In the present embodiment, 324 sets of chip group regions 20 are used to form a virtual cover pattern 310.

The arrangement of the specific unit regions is extracted from the virtual cover pattern 310 to define the predetermined pattern. Each of the probe needle groups 210 is arranged at the position corresponding to each of the specific unit regions. The probe needle groups 210 are equal in number to the chip group regions 20. In the present embodiment, 324 sets of probe needle groups are used to form the probe card 220 illustrated in FIG. 6. By the use of the probe card 220, all the semiconductor chips 110 in FIG. 1 can be tested with 3 indexes.

The probe card 220 is moved along the Hamilton path having a plurality of nodes. Each of the nodes corresponds to each of the unit regions 21-23. Within each chip group region 20, each probe needle group 210 transfers from node to node of the Hamilton path, when the probe card 200 is moved in accordance with the Hamilton path in a linear direction.

As described above, the chip group regions 10 and 20 has the simple shapes such as the square and the rectangular shapes, respectively. However, the shape of the chip group region is not limited to those described in the first and the second embodiments. The chip group region may have any kinds of shape which is formed of the unit regions equal in number to the indexes.

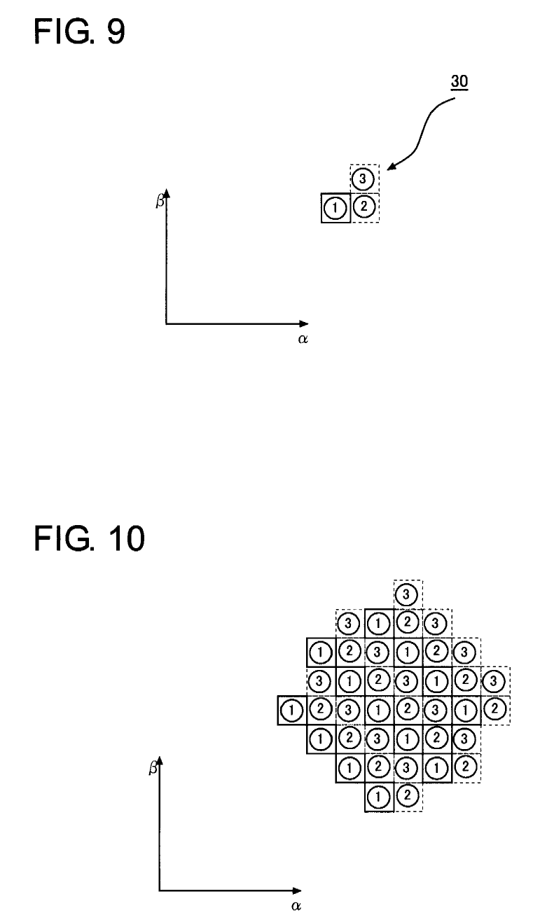

With reference to FIG. 9, each chip group region 30 is formed of three unit regions and has an L-shape. Herein, the number of indexes is 3. One of the unit regions is defined as a specific unit region.

As shown in FIG. 10, a plurality of chip group regions 30 are arranged without space therebetween to cover a size of the wafer 100 in the manner as described in the first and the second embodiments. The arrangement of the specific unit regions is extracted from the virtual cover pattern to define the predetermined pattern. Each probe needle group is arranged at the position corresponding to each specific unit region. In FIGS. 9 and 10, the specific unit region is depicted by the solid lines and the remaining unit regions are depicted by the broken lines.

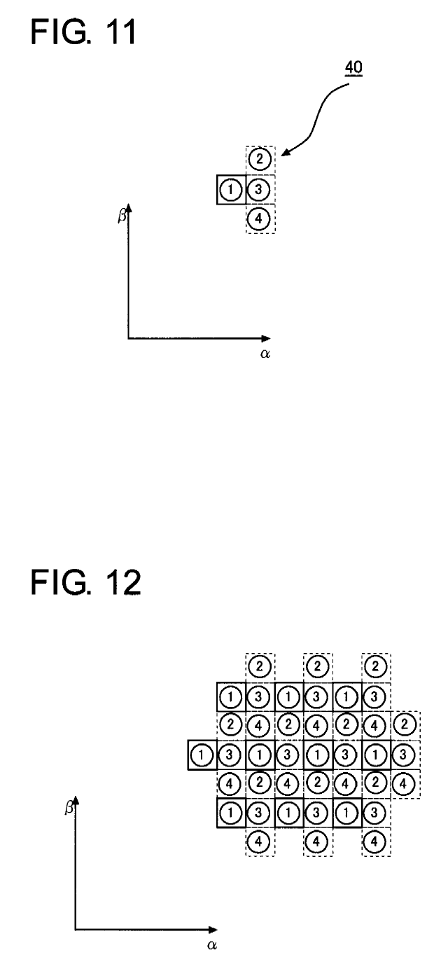

With reference to FIG. 11, each chip group region 40 is formed of four unit regions and has a T-shape. Herein, the number of indexes is 4. One of the unit regions is defined as a specific unit region.

As shown in FIG. 12, a plurality of chip group regions 40 are arranged without space therebetween to cover a size of the wafer 100 in the manner as described in the first and the second embodiments. The arrangement of the specific unit regions is extracted from the virtual cover pattern to define the predetermined pattern. Each probe needle group is arranged at the position corresponding to each specific unit region. In FIGS. 11 and 12, the specific unit region is depicted by the solid lines and the remaining unit regions are depicted by the broken lines.

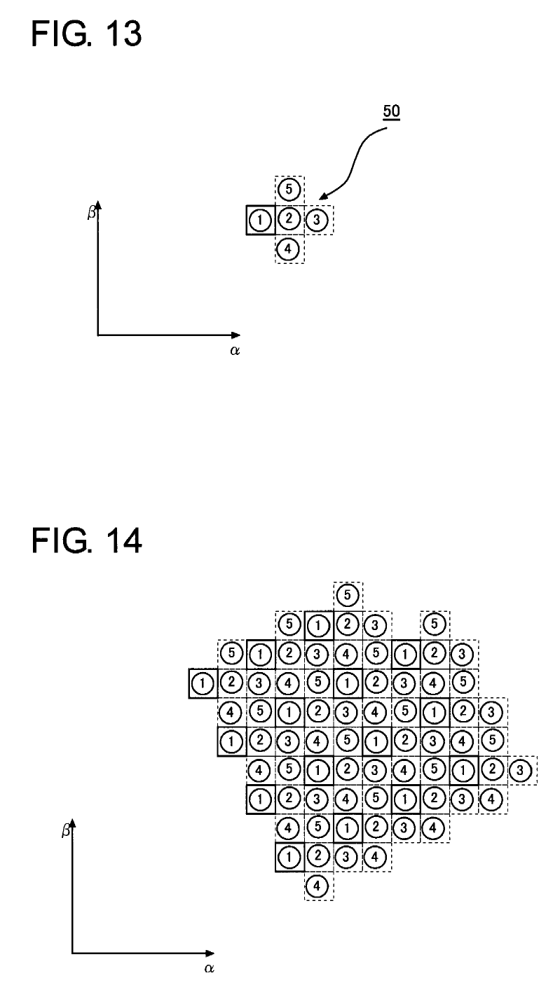

With reference to FIG. 13, each chip group region 50 is formed of five unit regions and has a cross shape. Herein, the number of indexes is 5. One of the unit regions is defined as a specific unit region.

As shown in FIG. 13, a plurality of chip group regions 50 are arranged without space therebetween to cover a size of the wafer 100 in the manner as described in the first and the second embodiments. The arrangement of the specific unit regions is extracted from the virtual cover pattern to define the predetermined pattern. Each probe needle group is arranged at the position corresponding to each specific unit region. In FIGS. 13 and 14, the specific unit region is depicted by the solid lines and the remaining unit regions are depicted by the broken lines.

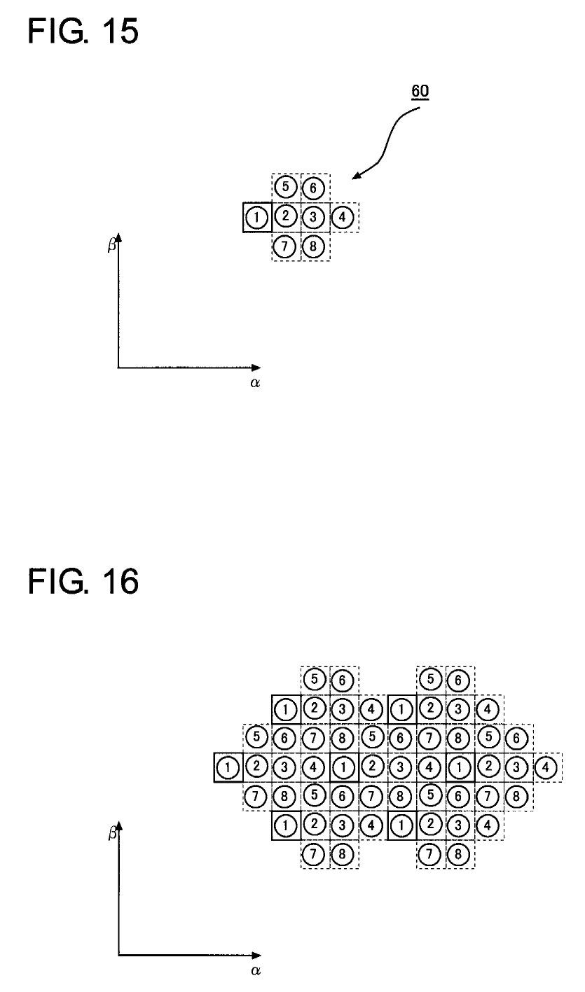

With reference to FIG. 15, each chip group region 60 is formed of eight unit regions. Herein, the number of indexes is 8. One of the unit regions is defined as a specific unit region.

As shown in FIG. 16, a plurality of chip group regions 60 are arranged without space therebetween to cover a size of the wafer 100 in the manner as described in the first and the second embodiments. The arrangement of the specific unit regions is extracted from the virtual cover pattern to define the predetermined pattern. Each probe needle group is arranged at the position corresponding to each specific unit region. In FIGS. 15 and 16, the specific unit region is depicted by the solid lines and the remaining unit regions are depicted by the broken lines.

Preferably, the chip group region may have a simple square or a rectangular shape. As apparent from FIGS. 9 to 16, in case where the chip group region has a complex shape, it might be difficult to arrange the plurality of chip group regions in the manner as described in the first and the second embodiments.

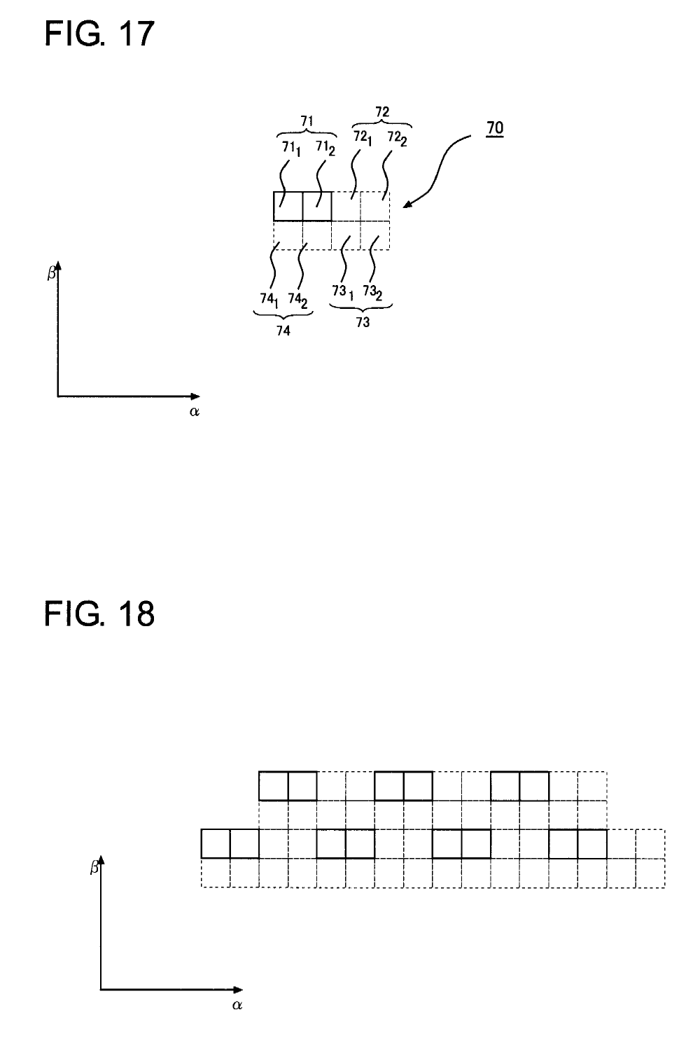

The probe card applying the concept of the present invention may be used in the case where the plurality of semiconductor chips are tested by a common drive. In this case, the unit region may be formed of two or more chip regions. With reference to FIG. 17, the unit regions 71, 72, 73, and 74 have pairs of two chip regions 71₁ and 71₂, 72₁ and 72₂, 73₁ and 73₂, and 74₁ and 74₄, respectively. The number of unit regions included in the chip group region is equal in number to the indexes. In the example shown in FIG. 17, four unit regions 71-74 are arranged adjacent to each other to form a substantially rectangular shape.

One of the unit regions 71-74 is defined as a specific unit region. In FIG. 17, the unit region 71 which is positioned at the upper left corner is defined as the specific unit region. In FIG. 17, the specific chip region is depicted by the solid lines.

As shown in FIG. 18, a plurality of chip group regions 70 are arranged without space therebetween to cover a size of the wafer 100 in the manner as described in the first and the second embodiments. The arrangement of the specific unit regions is extracted from the virtual cover pattern to define the predetermined pattern. Each probe needle group is arranged at the position corresponding to each specific unit region.

As regards the common drive, disclosures are made in U.S. Pat. No. 6,788,090 B (corresponding to JP 2001-296335A) and JP-A 2003-121500A, the contents of which are incorporated herein by reference.

The present application is based on Japanese patent application of JP 2006-69994 filed before the Japan Patent Office on Mar. 14, 2006, the contents of which are incorporated herein by reference.

While there has been described what is believed to be the preferred embodiment of the invention, those skilled in the art will recognize that other and further modifications may be made thereto without departing from the sprit of the invention, and it is intended to claim all such embodiments that fall within the true scope of the invention.

What is claimed is:

1. A probe card for use in testing a plurality of semiconductor chips formed on a wafer, each of the semiconductor chips having a plurality of pads, the probe card having a principal plane and comprising a plurality of probe needle groups, each of the probe needle groups having a plurality of probe needles equal in number to the pads of each of the semiconductor chips, the probe needle groups being arranged in a predetermined pattern, the predetermined pattern having an outline of a substantial circular shape, neighboring ones of the arranged probe needle groups being separated from each other at least in one of first and second directions by a distance corresponding to at least one of the semiconductor chips, the first and the second directions being perpendicular to each other and defining a plane parallel to the principal plane of the probe card.

2. The probe card according to claim 1, wherein the predetermined pattern is obtainable by:
assuming unit regions each comprised of at least one chip region, the chip region being substantially equal in size to one of the semiconductor chips;
assuming chip group regions each comprised of one or more unit regions including a specific unit region;
arranging the chip group regions without space therebetween to cover a size of the wafer, the arranged chip group regions forming a virtual cover pattern; and
extracting an arrangement of the specific unit regions from the virtual cover pattern to define the extracted arrangement as the predetermined pattern.

3. The probe card according to claim 2, wherein the chip group regions are equal in number to the probe needle groups.

4. The probe card according to claim 2, wherein each of the chip group regions has a square or a rectangular shape.

5. A probe card according to claim 2, wherein each of the chip group regions has first and second axes which are perpendicular to each other, the chip group regions being arranged so that the first axes of the chip group regions are directed in parallel with each other and that the second axes of the chip group regions are directed in parallel with each other.

6. The probe card according to claim 1 or 2, the probe card being connected to a tester upon actual use thereof, the tester having a plurality of signal line groups, wherein the probe needle groups are not greater in number than the signal line groups of the tester.

7. The probe card according to claim 2, wherein the unit regions included in each of the chip group regions are equal in number to minimum indexes need to be carried out for testing the plurality of semiconductor chips.

8. A method of designing a probe card for use in testing a plurality of semiconductor chips formed on a wafer, each of the semiconductor chips having a plurality of pads, the probe card having a principal plane and comprising a plurality of probe needle groups formed on the principal plane, each of the probe needle groups having a plurality of probe needles equal in number to the pads of each of the semiconductor chip,
the method comprising:
assuming unit regions each comprised of at least one chip region, the chip region being substantially equal in size to one of the semiconductor chips;
assuming chip group regions each comprised of one or more unit regions including a specific unit region;
arranging the chip group regions without space therebetween to cover a size of the wafer, the arranged chip group regions forming a virtual cover pattern;
extracting an arrangement of the specific unit regions from the virtual cover pattern to define the extracted arrangement as a predetermined pattern, the predetermined pattern having an outline of a substantial circular shape;
arranging the probe needle groups in accordance with the predetermined pattern.

9. The method according to claim 8, wherein the chip group regions are equal in number to the probe needle groups.

10. The method according to claim 8, wherein each of the chip group regions has a square or a rectangular shape.

11. The method according to claim 8, wherein each of the chip group regions has first and second axes which are perpendicular to each other, the chip group regions being arranged so that the first axes of the chip group regions are directed in parallel with each other and that the second axes of the chip group regions are directed in parallel with each other.

12. The method according to claim 8, wherein the probe card being connected to a tester upon actual use thereof, the tester having a plurality of signal line groups, the probe needle groups being smaller in number than the signal line groups of the tester.

13. The method according to claim 8, wherein the unit regions included in each of the chip group regions are equal in number to minimum indexes need to be carried out for testing the plurality of semiconductor chips.

14. A method of testing a plurality of semiconductor chips formed on a wafer by using a probe card, neighboring ones of the semiconductor chips having a predetermined distance between their centers, each of the semiconductor chips having a plurality of pads, the probe card having a principal plane and comprising a first number of probe needle groups formed on the principal plane, each of the probe needle groups having a plurality of probe needles equal in number to the pads of each of the semiconductor chips, the probe needle groups being arranged in a predetermined pattern, the predetermined pattern being obtained by: assuming unit regions each comprised of at least one chip region, the chip region being substantially equal in size to one of the semiconductor chips; assuming chip group regions each comprised of a second number of unit regions including a specific unit region; arranging the chip group regions without space therebetween to cover a size of the wafer, the arranged chip group regions forming a virtual cover pattern; and extracting an arrangement of the specific unit regions from the virtual cover pattern to define the extracted arrangement as the predetermined pattern,
the testing method comprising:
connecting the probe card to a tester having a third number of signal lines groups, the third number being not smaller than the first number;
repeatedly carrying out predetermined processes the second number of times, the predetermined processes comprising:
probing a fourth number of semiconductor chips once by using the probe card, the fourth number being not greater than the first number; and
moving the probe card in accordance with a Hamilton path by the predetermined distance once, the Hamilton path having the second number of nodes, the nodes corresponding to respective chip regions of each of the unit regions, the movement being from a current node to a next node on the Hamilton path.
